(19) United States
(12) Patent Application Publication
(10) Pub. No.: US 2025/0318286 A1
(43) Pub. Date: Oct. 9, 2025

(54) SEMICONDUCTOR LIGHT RECEIVING ELEMENT

(71) Applicant: HAMAMATSU PHOTONICS K.K., Hamamatsu-shi, Shizuoka (JP)

(72) Inventors: Keiki TAGUCHI, Hamamatsu-shi, Shizuoka (JP); Kenji MAKINO, Hamamatsu-shi, Shizuoka (JP); Yoshiaki OHSHIGE, Hamamatsu-shi, Shizuoka (JP); Hajime ISHIHARA, Hamamatsu-shi, Shizuoka (JP)

(73) Assignee: HAMAMATSU PHOTONICS K.K., Hamamatsu-shi, Shizuoka (JP)

(21) Appl. No.: 18/865,422

(22) PCT Filed: Feb. 15, 2023
(86) PCT No.: PCT/JP2023/005253

§ 371 Date: Nov. 13, 2024

(30) Foreign Application Priority Data
Jun. 3, 2022 (JP) 2022-091033
Nov. 16, 2022 (JP) 2022-183585

(51) Int. Cl. H10F 30/222; G02B 6/42; H10F 77/40

(52) U.S. Cl. CPC H10F 30/222; H10F 77/413; G02B 6/4204

(57) ABSTRACT

Provided is a semiconductor light-receiving element including a substrate, a semiconductor lamination portion formed on the substrate, and first and second electrodes electrically connected to the semiconductor lamination portion. The semiconductor lamination portion includes a light absorbing layer that contains InGaAs and includes a first region that has a first conductivity type, a first semiconductor layer located between the substrate and the light absorbing layer, a second semiconductor layer located on a side opposite to the substrate with respect to the light absorbing layer, and a capacitance reducing layer that has the first conductivity type, consists of any one of InP, InGaAsP, InAsP, and AlInGaAs, and is located between one semiconductor layer from among the first semiconductor layer and the second semiconductor layer, and the light absorbing layer.

### TECHNICAL FIELD

The present disclosure relates to a semiconductor light-receiving element.

### BACKGROUND ART

Patent Literature 1 discloses a photoelectric conversion device. The photoelectric conversion device has a lamination structure obtained by sequentially laminating an n-InP substrate, a non-doped InP junction capacitance reducing layer, a non-doped InGaAs light absorbing layer, a non-doped InP junction capacitance reducing layer, and a p-InP window region.

### CITATION LIST

### Patent Literature

Patent Literature 1: Japanese Unexamined Patent Publication No. H6-275860

### SUMMARY OF INVENTION

### Technical Problem

In the photoelectric conversion device described in Patent Literature 1, the thickness of each of the junction capacitance reducing layers is adjusted so that traveling times of electrons and holes are the same as each other, thereby reducing a phase difference in currents generated by the traveling of the electrons and the holes.

By the way, in a semiconductor light-receiving element such as the photoelectric conversion device described in Patent Literature 1, when a barrier for electrons between a light absorbing layer and the capacitance reducing layer is large, the electrons may need to overcome the barrier to be detected. As a result, there is a concern that a deterioration in response performance.

An object of the present disclosure is to provide a semiconductor light-receiving element capable of suppressing a deterioration in response performance.

### Solution to Problem

A semiconductor light-receiving element according to the present disclosure is [1] “A semiconductor light-receiving element including: a substrate; a semiconductor lamination portion formed on the substrate; and first and second electrodes electrically connected to the semiconductor lamination portion, in which the semiconductor lamination portion includes a light absorbing layer that contains InGaAs and includes a first region that has a first conductivity type, a first semiconductor layer located between the substrate and the light absorbing layer, a second semiconductor layer located on a side opposite to the substrate with respect to the light absorbing layer, and a capacitance reducing layer that has the first conductivity type, consists of any one of InP, InGaAsP, InAsP, and AlInGaAs, and is located between one semiconductor layer from among the first semiconductor layer and the second semiconductor layer and the light absorbing layer, the other semiconductor layer from among the first semiconductor layer and the second semiconductor layer includes a second region that has a second conductivity type and forms a PN junction with the first region of the light absorbing layer, the first electrode is connected to the first semiconductor layer, the second electrode is connected to the second semiconductor layer, a carrier concentration of the capacitance reducing layer is 5×10¹⁵ cm⁻³ or less, and is higher than a carrier concentration of the first region of the light absorbing layer, and a band gap of the capacitance reducing layer is larger than a band gap of the light absorbing layer”.

In the semiconductor light-receiving element, in the semiconductor lamination portion, the first semiconductor layer, the light absorbing layer, and the second semiconductor layer are sequentially laminated from the substrate side, and the capacitance reducing layer is interposed between one of the first semiconductor layer and the second semiconductor layer, and the light absorbing layer. In addition, a PN junction is formed between the other of the first semiconductor layer and the second semiconductor layer, and the light absorbing layer. In addition, the carrier concentration of the capacitance reducing layer is set to be higher than the carrier concentration in the first region, which is the first conductivity type, of the light absorbing layer. Accordingly, a barrier between the light absorbing layer and the capacitance reducing layer with respect to electrons is further reduced as compared with a case where the carrier concentration of the capacitance reducing layer is equal to or less than the carrier concentration of the light absorbing layer. As a result, a deterioration in response performance is suppressed. Note that, in the semiconductor light-receiving element, the band gap of the capacitance reducing layer is set to be larger than the band gap of the light absorbing layer. Accordingly, light absorbed in the light absorbing layer is suppressed from being absorbed in the capacitance reducing layer. As a result, generation of slow carriers is suppressed, and a decrease in response speed is suppressed.

The semiconductor light-receiving element according to the present disclosure may be [2] “The semiconductor light-receiving element according to [1], in which the other semiconductor layer includes a third region that has the first conductivity type and surrounds the second region when viewed from a lamination direction of the semiconductor lamination portion”. In this case, as an example, it is possible to easily form the second region that has the second conductivity type and the third region that has the first conductivity type and surrounds the second region by diffusing second conductivity type impurities into a region of a part of the semiconductor layer that has the first conductivity type by a method such as thermal diffusion and ion implantation.

The semiconductor light-receiving element according to the

present disclosure may be [3] “The semiconductor light-receiving element according to [2], in which the second region extends to the inside of the light absorbing layer from the other semiconductor layer”. In this way, the semiconductor region that has the second conductivity type may extend to the inside of the light absorbing layer.

The semiconductor light-receiving element according to the present disclosure may be [4] “The semiconductor light-receiving element according to [1], in which the other semiconductor layer consists of the second region”. In this case, it is possible to easily form a semiconductor layer consisting of the second region that has the second conductivity type by a method such as epitaxial growth as an example.

The semiconductor light-receiving element according to the present disclosure may be [5] “The semiconductor light-receiving element according to [4], in which the second region includes another light absorbing layer that has the second conductivity type and is laminated on the light absorbing layer”. In this case, it is possible to achieve contact with the electrode that has the second conductivity type in the light absorbing layer that has the second conductivity type.

The semiconductor light-receiving element according to the present disclosure may be [6] “The semiconductor light-receiving element according to any one of [1] to [5], in which the first semiconductor layer includes a buffer layer”. In this case, the buffer layer can be used to provide various functions to the first semiconductor layer such as forming a contact with the first electrode or relaxation of distortion caused by a difference in lattice constant between the substrate and the light absorbing layer.

The semiconductor light-receiving element according to the present disclosure may be [7] “The semiconductor light-receiving element according to [6], in which the buffer layer has the first conductivity type, and a carrier concentration of the buffer layer is higher than the carrier concentration of the capacitance reducing layer”. In this case, a deterioration in response performance can be reliably suppressed.

The semiconductor light-receiving element according to the present disclosure may be [8] “The semiconductor light-receiving element according to any one of [1] to [7], in which the thickness of the light absorbing layer is 0.6 μm or more and 1.8 μm or less”. In this case, a traveling distance of electrons is shortened, and thus an increase in speed is achieved.

The semiconductor light-receiving element according to the present disclosure may be [9] “The semiconductor light-receiving element according to any one of [1] to [8], in which a carrier concentration in the first region of the light absorbing layer is 1×10¹⁴ cm⁻³ or more and 3×10¹⁵ cm⁻³ or less”. In this way, the carrier concentration in the first region of the light absorbing layer can be set as described above in a range lower than the carrier concentration in the second region of the capacitance reducing layer.

The semiconductor light-receiving element according to the present disclosure may be [10] “The semiconductor light-receiving element according to any one of [1] to [8], in which the thickness of the capacitance reducing layer is 0.1 μm or more and 3.0 μm or less”. In this way, the thickness of the capacitance reducing layer can be set to the above-described range.

The semiconductor light-receiving element according to the present disclosure may be [11] “The semiconductor light-receiving element according to any one of [1] to [10], in which the carrier concentration of the capacitance reducing layer is 1.5×10¹⁴ cm⁻³ or more and 5×10¹⁵ cm⁻³ or less”. In this case, it is possible to suitably deplete the capacitance reducing layer when a bias is applied while reducing the barrier caused by the capacitance reducing layer.

The semiconductor light-receiving element according to the present disclosure may be [12] “The semiconductor light-receiving element according to any one of [1] to [11], in which a sensitivity wavelength region of the capacitance reducing layer is 1.31 μm or less”. In this case, in the capacitance reducing layer, it is possible to suppress absorption of light in a wavelength band for communication such as a band of 1.3 μm, a band of 1.55 μm, and a band of 1.6 μm.

The semiconductor light-receiving element according to the present disclosure may be [13] “The semiconductor light-receiving element according to [6] or [7], in which the thickness of the buffer layer is 0.5 μm or more to 2.5 μm or less”. In this way, the thickness of the buffer layer can be set to the above-described range.

The semiconductor light-receiving element according to the present disclosure may be [14] “The semiconductor light-receiving element according to any one of [6], [7], and [13], in which a carrier concentration of the buffer layer is 5×10¹⁶ cm⁻³ or more and 5×10¹⁸ cm⁻³ or less”. In this way, the carrier concentration of the buffer layer can be set to the above-described range.

### Advantageous Effects of Invention

According to the present disclosure, it is possible to provide a semiconductor light-receiving element capable of suppressing a deterioration in response performance.

### BRIEF DESCRIPTION OF DRAWINGS

FIG. 1 is a schematic side view illustrating an optical device according to an embodiment.

FIG. 2 is a plan view of a semiconductor light-receiving element illustrated in FIG. 1.

FIG. 3 is a cross-sectional view taken along line III-III in FIG. 2.

FIG. 4 is a cross-sectional view taken along line IV-IV in FIG. 2.

FIG. 5 is a cross-sectional view taken along line V-V in FIG. 2.

FIG. 6 is a cross-sectional view illustrating a semiconductor light-receiving element according to a modification example.

FIG. 7 is a cross-sectional view illustrating a semiconductor light-receiving element relating to another modification example.

FIG. 8 is a view illustrating a modification example relating to a mounting method of the semiconductor light-receiving element.

### DESCRIPTION OF EMBODIMENTS

Hereinafter, an embodiment will be described in detail with reference to the accompanying drawings. Note that, in the drawings, the same reference numeral will be given to the same or equivalent element, and redundant description thereof may be omitted.

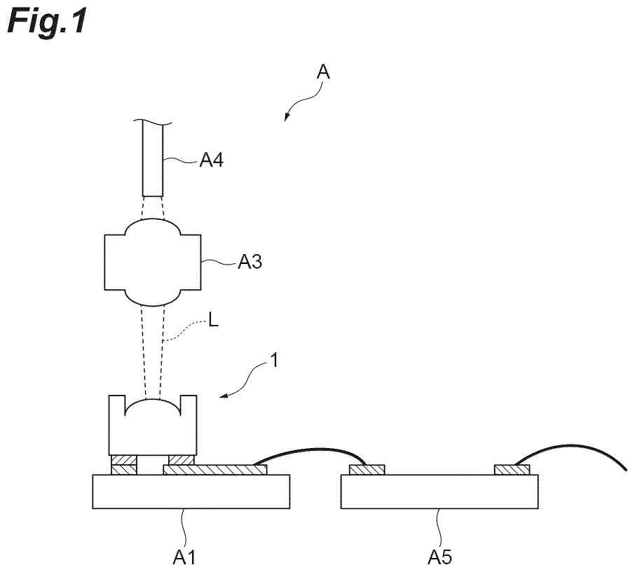

FIG. 1 is a schematic side view illustrating an optical device according to an embodiment. As illustrated in FIG. 1, an optical device A includes a semiconductor light-receiving element 1. As an example, the optical device A can target light in wavelength bands for optical communication such as a band of 1.3 μm (Original-band (O-band)), a band of 1.55 μm (conventional-band (C-band)), and a band of 1.6 μm (long-wavelength-band (L-band)), may convert the light into an electrical signal, and output the electrical signal.

The band of 1.3 μm is, for example, a wavelength range of from 1.26 μm to 1.36 μm. The band of 1.55 μm is, for example, a wavelength range of from 1.53 μm to 1.565 μm. The band of 1.6 μm is, for example, a wavelength range of greater than 1.565 μm and 1.625 μm or less. In addition, the light in a wavelength band for communication is light having a peak within a wavelength range of any of the wavelength bands (that is, a wavelength other than the peak may be out of the wavelength range of the wavelength band).

Accordingly, the semiconductor light-receiving element 1 may also target the wavelength bands, may receive incident light L having a wavelength pertaining to at least one wavelength band among the wavelength bands, and may generate an electrical signal in correspondence with the incident light. The semiconductor light-receiving element 1 is mounted on a submount A1. The light L is guided by an optical fiber A4, and is condensed toward a light-receiving unit of the semiconductor light-receiving element 1 by a lens A3.

An electrical signal generated by the semiconductor light-receiving element 1 is input to a transimpedance amplifier (TIA) A5 via electrode pads (schematically by hatching in FIG. 1 and the like) and wires provided on the submount A1, and is converted into a voltage by the transimpedance amplifier A5 before being output to the outside. Note that, here, the semiconductor light-receiving element 1 is mounted on the submount A1 with a rear surface 10b of the following substrate 10 facing the lens A3 and optical fiber A4. Note that, here, the semiconductor light-receiving element 1 is a rear-surface incident type in which light is incident toward the following semiconductor lamination portion 20 from the substrate 10 side. More specifically, in this example, the semiconductor light-receiving element 1 receives light incident from the following rear surface 10b, and the light is guided from the substrate 10 side to the semiconductor lamination portion 20.

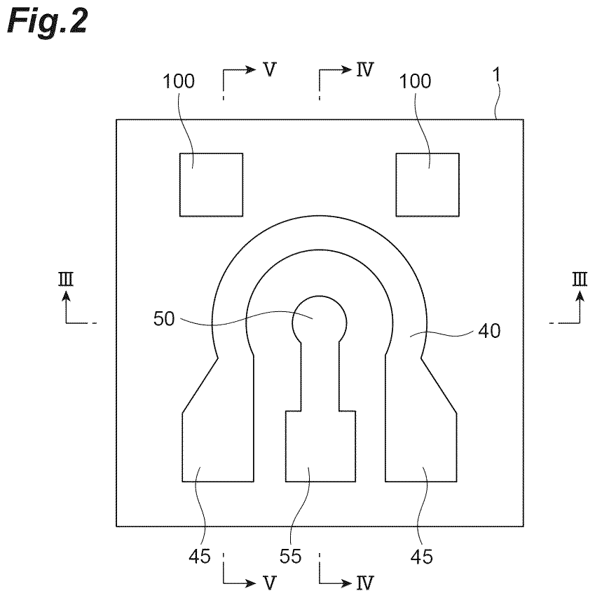

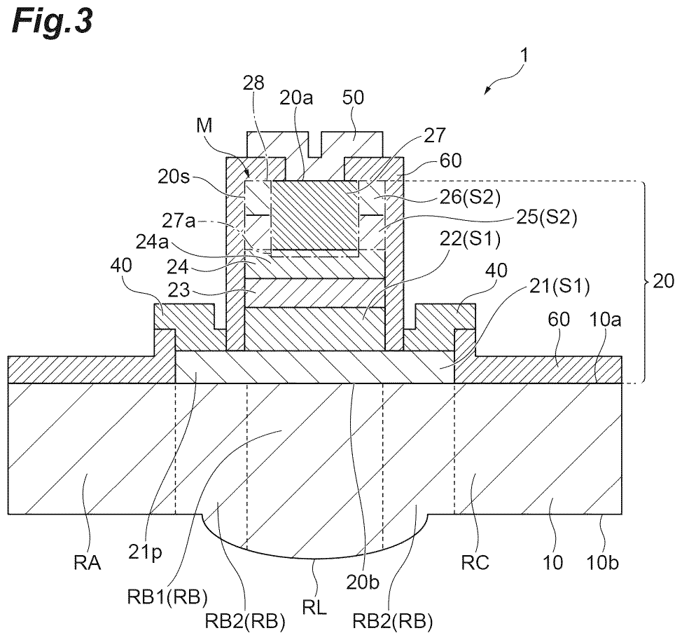

FIG. 2 is a plan view of the semiconductor light-receiving element shown in FIG. 1. FIG. 3 is a cross-sectional view taken along line III-III in FIG. 2. As illustrated in FIGS. 2 and 3, the semiconductor light-receiving element 1 includes the substrate 10, the semiconductor lamination portion 20, a first electrode 40 (here, a cathode), and a second electrode 50 (here, an anode).

The substrate 10 contains a semi-insulating semiconductor. Here,

the substrate 10 is a semi-insulating semiconductor substrate consisting of, for example, InP. The substrate 10 includes a front surface 10a and the rear surface 10b on a side opposite to the front surface 10a. In addition, the substrate 10 includes a plurality of regions RA, RB (first region), and RC arranged sequentially along the front surface 10a and the rear surface 10b. The region RB is a region between the region RA and the region RC. More specifically, the region RB includes a central side region RB1, and regions RB2 located on both sides (the regions RA and RC sides) of the region RB1. Here, the rear surface 10b of the substrate 10 is an incident surface of the light L, and a lens RL that condenses the light L is formed in the rear surface 10b. The lens RL is formed to partially overlap the region RB2 with the region RB1 set as a center.

The semiconductor lamination portion 20 is formed on the substrate 10. More specifically, the semiconductor lamination portion 20 is formed on the front surface 10a on the region RB of the substrate 10. The semiconductor lamination portion 20 includes a rear surface 20b on the substrate 10 side and a front surface 20a on a side opposite to the substrate 10. The semiconductor lamination portion 20 includes a buffer layer 21, a buffer layer 22, a capacitance reducing layer 23, a light absorbing layer 24, a cap layer 25, and a contact layer 26 which are sequentially laminated from the substrate 10 side. Here, the rear surface 20b of the semiconductor lamination portion 20 is a surface on a side opposite to the light absorbing layer 24 in the buffer layer 21, and is in contact with the front surface 10a of the substrate 10. In addition, the surface 20a of the semiconductor lamination portion 20 is a surface on a side opposite to the light absorbing layer 24 in the contact layer 26.

The buffer layer 21 has a first conductivity type (here, an N type, and as an example, an N⁺ type). The buffer layer 21 is provided so as to overlap the region RB2 with the region RB1 set as a center. Layers (the buffer layer 22, the capacitance reducing layer 23, the light absorbing layer 24, the cap layer 25, and the contact layer 26) of the semiconductor lamination portion 20 except for the buffer layer 21 are provided on a region overlapping the region RB1 in the buffer layer 21. Accordingly, the buffer layer 21 is provided with a portion 21p that is exposed from the layers of the semiconductor lamination portion 20 except for the buffer layer 21, and a protective film 60 to be described later, and the layers of the semiconductor lamination portion 20 except for the buffer layer 21 constitute a semiconductor mesa M. In the semiconductor light-receiving element 1, a junction with the first electrode 40 is formed in the portion 21p of the buffer layer 21. For example, the buffer layer 21 contains InP, and consists of N⁺-InP as an example.

The buffer layer 22 has a first conductivity type (here, an N-type, and as an example, N⁺ type). The buffer layer 22 contains, for example, InP or InGaAsP, and consists of N⁺-InP or N⁺-InGaAsP as an example. The buffer layer 21 and the buffer layer 22 constitute a first semiconductor layer S1 (here, the first conductivity type) located between the substrate 10 and the light absorbing layer 24.

A carrier concentration of the buffer layer 22 is higher than a carrier concentration of the capacitance reducing layer 23 to be described later. As an example, the carrier concentration of the buffer layer 22 is from 5×10¹⁶ cm⁻³ to 5×10¹⁸ cm⁻³. The thickness of the buffer layer 22 is, for example, from 0.5 μm to 2.5 μm.

Note that, the buffer layers 21 and 22 may have a lattice constant between a lattice constant of the substrate 10 and a lattice constant of the light absorbing layer 24 to function as a strain relaxation layer. That is, the semiconductor lamination portion 20 may include a plurality of strain relaxation layers (step layers) arranged so that the lattice constant becomes close to the lattice constant of the light absorbing layer 24 in a stepwise manner as going from the substrate 10 toward the light absorbing layer 24.

The capacitance reducing layer 23 has the first conductivity type (here, an N type, and as an example, N⁻ type). For example, the capacitance reducing layer 23 contains any one among InP, InGaAsP, InAsP, and AlInGaAs, and consists of any one of N⁻-InP, N⁻-InGaAsP, N⁻-InAsP, and N⁻-AlInGaAs. The capacitance reducing layer 23 is located between the first semiconductor layer S1 and the light absorbing layer 24. Here, the capacitance reducing layer 23 is in contact with the first semiconductor layer S1 and the light absorbing layer 24.

The light absorbing layer 24 has the first conductivity type (here, an N type, and as an example, an N⁻ type). Here, the light absorbing layer 24 consists of N⁻-InₓGa₁₋ₓAs. An In composition x of the light absorbing layer 24 may be 0.55 or more (and less than 1). In this case, the In composition x is 0.59 as an example. The thickness of the light absorbing layer 24 (thickness along a lamination direction of the semiconductor lamination portion 20) is from 0.6 μm to 1.8 μm, and here, as an example, the thickness is 0.7 μm. Note that, the light absorbing layer 24 may contain Al, P, Sb, N, or other materials with a band gap, for example, in a range of 0.72 eV or less (for example, the light absorbing layer 24 may be set as an absorption layer of a mixed crystal of InGaAs and the materials). In this case, as an example, the light absorbing layer 24 may consist of InGaAsP, AlGalnAs, InGaAsSb, or InGaAsN. The ratio of Al, P, Sb, and N (or other materials) mixed into InGaAs can be set to, for example, 5% or less, or 10% or less.

Here, the capacitance reducing layer 23 has a carrier concentration higher than a carrier concentration of the light absorbing layer 24 in a range of 5×10¹⁵ cm⁻³ or less as an example. As an example, the carrier concentration of the capacitance reducing layer 23 is from 1.5×10¹⁴ cm⁻³ to 5×10¹⁵ cm⁻³, and an impurity concentration of the light absorbing layer 24 is from 1×10¹⁴ cm⁻³ to 3×10¹⁵ cm⁻³. In addition, the capacitance reducing layer 23 has a band gap larger than a band gap of the light absorbing layer 24. When the band gap of the light absorbing layer 24 is 0.72 eV or less as described above, the band gap of the capacitance reducing layer 23 can be set to a range of more than 0.72 eV and equal to or less than 1.35 eV.

The capacitance reducing layer 23 needs to have the carrier concentration higher than that of the light absorbing layer 24 and to be depleted when a bias is applied as described above. The reason for this is as follows. As described above, since the capacitance reducing layer 23 has a band gap larger than that of the light absorbing layer 24, in a case where the carrier concentration is low, a barrier may be formed in a conduction band, the movement of carriers with a large barrier may be hindered, and the carriers may not be extracted properly.

In addition, since capacitance reducing layer 23 needs to be depleted when a bias is applied, an upper limit of the carrier concentration may be set to 5.0×10¹⁵ cm⁻³ as described above. Furthermore, the capacitance reducing layer 23 may have a composition that does not absorb incident light (that is, the band gap may be wider than that of light absorbing layer 24). This is because when the capacitance reducing layer 23 absorbs incident light, carriers are generated in capacitance reducing layer 23. Since the carriers are extracted as signals from the capacitance reducing layer 23 via the light absorbing layer 24, there is a concern that the carriers may become slow carriers and may deteriorate responsiveness characteristics. As an example, a sensitivity wavelength range of capacitance reducing layer 23 may be set to 1.31 μm or less. As described above, when a relationship between the capacitance

reducing layer 23 and the light absorbing layer 24 is set as described above, capacitance can be reduced without lowering the response of the carriers. The thickness of the capacitance reducing layer 23 may be set to from 0.1 μm to 3.0 μm.

Note that, in the semiconductor light-receiving element 1, the light absorbing layer 24 is a single layer. The configuration in which the light absorbing layer 24 is a single layer represents that the light absorbing layer 24 does not have a lamination structure formed by laminating two or more layers having different compositions or characteristics. More specifically, the configuration in which the light absorbing layer 24 is a single layer represents, for example, that the light absorbing layer 24 does not have a superlattice structure formed by repeatedly laminating a plurality of layers having different compositions.

The cap layer 25 has the first conductivity type (here, an N type, and as an example, an N⁻ type). The cap layer 25 contains, for example, InP or InGaAsP. As an example, the cap layer 25 consists of N⁻-InP or N⁻-InGaAsP. A carrier concentration of the cap layer 25 is, for example, from 1×10¹⁴ cm⁻³ to 1×10¹⁶ cm⁻³. The thickness of the cap layer 25 is, for example, from 0.1 μm to 0.5 μm.

The contact layer 26 has a first conductivity type (here, an N-type, and as an example, an N⁻ type). The contact layer 26 contains, for example, InGaAs and consists of N⁻-InGaAs as an example. A carrier concentration of the contact layer 26 is, for example, from 1×10¹⁴ cm⁻³ to 1×10¹⁶ cm⁻³. The thickness of the contact layer 26 is, for example, from 0.1 μm to 0.2 μm.

In the semiconductor lamination portion 20, the second region 27 that has a second conductivity type (here, a P type, and as an example, a P⁺ type) is formed. The second region 27 can be formed, for example, by thermal diffusion, ion implantation, or the like. The second region 27 extends from the front surface 20a of the semiconductor lamination portion 20 toward the substrate 10 side. Here, the second region 27 is formed so as to extend from the contact layer 26 to the light absorbing layer 24 via the cap layer 25. In this way, the cap layer 25 and the contact layer 26 constitute a second semiconductor layer S2 located on a side opposite to the substrate 10 with respect to the light absorbing layer 24. The second semiconductor layer S2 includes the second region 27 that forms a PN junction (here, the second conductivity type) with the light absorbing layer 24.

Here, the second region 27 is formed at a part (for example, a part including the center) in a width direction of the second semiconductor layer S2 (a direction intersecting the lamination direction of the semiconductor lamination portion 20). Accordingly, here, the second semiconductor layer S2 includes a third region 28 that is the first conductivity type and surrounds the second region 27 when viewed from the lamination direction of the semiconductor lamination portion 20.

The second region 27 of the second semiconductor layer S2 may extend from the second semiconductor layer into the light absorbing layer 24. In this case, the light absorbing layer 24 includes a fifth region 27a that has the second conductivity type and is an extended portion of the second region 27, and a first region 24a that has the first conductivity type other than the fifth region 27a. In this case, when the thickness of the light absorbing layer 24 is, for example, 0.7 μm, the fifth region 27a can be formed in a range of 0.2 μm of the light absorbing layer 24 on the cap layer 25 side. That is, in this example, the first region 24a with a thickness of approximately 0.5 μm and the fifth region 27a with a thickness of 0.2 μm are included at the inside of the light absorbing layer 24, and a boundary between the regions is formed. When the fifth region 27a is a P⁺ type, a terminal end thereof is, for example, a position where the P type carrier concentration is 1×10¹⁷ cm⁻³or less.

On the other hand, when the second region 27 of the second semiconductor layer S2 does not reach the inside of the light absorbing layer 24, the entire light absorbing layer 24 becomes the first region 24a having the first conductivity type. In this embodiment, the N⁺ type represents that an N type carrier concentration is approximately 1×10¹⁷ cm⁻³ or more. The N⁻ type represents that the N type carrier concentration is approximately 3.0×10¹⁶ cm³ or less that is relatively lower as compared with the N+ type. Also, the P⁺ type represents that the P type carrier concentration is approximately 1×10¹⁷ cm⁻³ or more.

Here, the semiconductor light-receiving element 1 includes the protective film 60. The protective film 60 is, for example, an insulating film. A part of the front surface 20a (top surface) of the semiconductor lamination portion 20 and a side surface 20s of the semiconductor lamination portion 20 extending from a peripheral edge of the front surface 20a toward the substrate 10 side are covered with the protective film 60. On the other hand, the remaining portion of the front surface 20a of the semiconductor lamination portion 20 (here, the surface of the second region 27) is exposed from the protective film 60. Then, the second electrode 50 is formed on the portion of the front surface 20a exposed from the protective film 60, and a junction between the second electrode 50 and the second region 27 (contact layer 26) is formed. That is, the second electrode 50 is connected to a portion (second region 27) that is the second conductivity type and is located on a side opposite to the substrate 10 with respect to the light absorbing layer 24 in the semiconductor lamination portion 20. On the other hand, the first electrode 40 is connected to the portion 21p (a portion of the buffer layer 21 which is exposed from the protective film 60) that has the first conductivity type and is located on the substrate 10 side with respect to the light absorbing layer 24 in the semiconductor lamination portion 20.

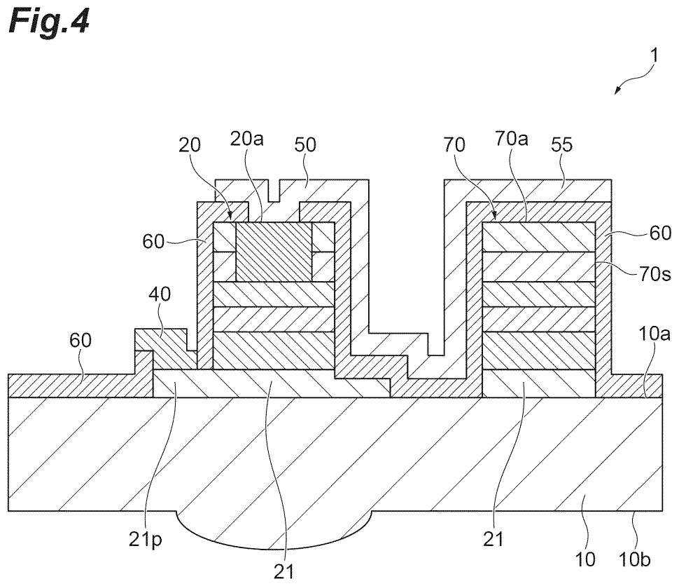

FIG. 4 is a cross-sectional view taken along line IV-IV in FIG. 2. As illustrated in FIGS. 2 and 4, a semiconductor lamination portion 70 is formed on the front surface 10a of the substrate 10 via the buffer layer 21. A structure of the semiconductor lamination portion 70 is similar to the configuration of the semiconductor lamination portion 20 excluding the buffer layer 21 except that the second region 27 that is the second conductivity type is not formed. The semiconductor lamination portion 70 is entirely covered with the protective film 60.

Here, the second electrode 50 extends from the front surface 20a of the semiconductor lamination portion 20 to a top surface 70a (a surface facing a side opposite to the substrate 10) of the semiconductor lamination portion 70, and forms an anode pad 55 on the top surface 70a. That is, the anode pad 55 is formed on the top surface 70a of the semiconductor lamination portion 70, and is electrically connected to the second electrode 50 via the protective film 60.

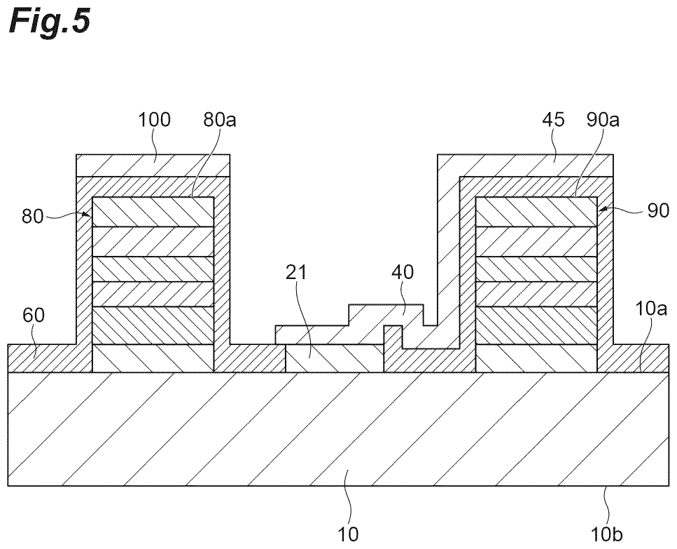

FIG. 5 is a cross-sectional view taken along line V-V in FIG. 2. As illustrated in FIGS. 2 and 5, semiconductor lamination portions 80 and 90 are formed on the front surface 10a of the substrate 10 via the buffer layer 21. A structure of the semiconductor lamination portions 80 and 90 is similar to the structure of the semiconductor lamination portion 20 excluding the buffer layer 21 except that the second region 27 that is the second conductivity type is not formed. The semiconductor lamination portions 80 and 90 are entirely covered with the protective film 60. Here, the first electrode 40 extends from a portion bonded to the buffer layer 21 to a top surface 90a (a surface facing an opposite side to the substrate 10) of the semiconductor lamination portion 90, and forms a cathode pad 45 on the top surface 90a.

That is, the cathode pad 45 electrically connected to the first electrode 40 is formed on the top surface 90a of the semiconductor lamination portion 90 via the protective film 60. On the other hand, a dummy pad 100 is formed on the top surface 80a of the semiconductor lamination portion 80 via the protective film 60. As illustrated in FIG. 2, the cathode pad 45 (and the semiconductor lamination portion 90) is formed as a pair so as to sandwich the anode pad 55 (and the semiconductor lamination portion 70), and a pair of dummy pads 100 (and the semiconductor lamination portion 80) are also formed.

In the optical device A, the semiconductor light-receiving element 1 is disposed and mounted on the submount A1 in such a manner that the front surface 10a of the substrate 10 faces the submount A1 side, that is, the rear surface 10b of the substrate 10 faces a side opposite to the submount A1. According to this, the pair of cathode pads 45, the anode pad 55, and the pair of dummy pads 100 are connected to respective electrode pads provided on the submount A1. As a result, the cathode pads 45 and the anode pad 55 are connected to electrodes electrically connected to the transimpedance amplifier A5 on the submount A1.

As described above, in the semiconductor light-receiving element 1 according to this embodiment, in the semiconductor lamination portion 20, the first semiconductor layer S1, the light absorbing layer 24, and the second semiconductor layer S2 are laminated sequentially from the substrate 10 side, and the capacitance reducing layer 23 is interposed between the first semiconductor layer S1 and the light absorbing layer 24. The second semiconductor layer S2 forms a PN junction with the light absorbing layer 24. In addition, the carrier concentration of the capacitance reducing layer 23 is higher than the carrier concentration in the light absorbing layer 24 (first region 24a that has the first conductivity type). Accordingly, as compared with a case where the carrier concentration of the capacitance reducing layer 23 is equal to or lower than the carrier concentration of the light absorbing layer 24, a barrier between the light absorbing layer 24 and the capacitance reducing layer 23 against electrons is smaller. As a result, a deterioration in response performance is suppressed.

Note that, in the semiconductor light-receiving element 1 according to this embodiment, the band gap of capacitance reducing layer 23 is set to be larger than the band gap of light absorbing layer 24. According to this, light absorbed in light absorbing layer 24 is prevented from being absorbed in capacitance reducing layer 23. As a result, generation of slow carriers is suppressed, and a decrease in response speed is suppressed.

In addition, in the semiconductor light-receiving element 1 according to this embodiment, the second semiconductor layer S2 includes the third region 28 that has the first conductivity type and surrounds the second region 27 when viewed from the lamination direction of the semiconductor lamination portion 20. In this case, as an example, it is possible to easily form the second region 27 that has the second conductivity type and the third region 28 that has the first conductivity type and surrounds the second region 27 by diffusing second conductivity type impurities into a region of a part of the semiconductor layer that has the first conductivity type by a method such as thermal diffusion and ion implantation.

In addition, in the semiconductor light-receiving element 1 according to this embodiment, the second region 27 extends from the second semiconductor layer S2 to the inside of the light absorbing layer 24. In this manner, a semiconductor region that has the second conductivity type may extend into the light absorbing layer 24.

In addition, the semiconductor light-receiving element 1 according to this embodiment, the first semiconductor layer S1 includes the buffer layers 21 and 22. Accordingly, it becomes possible to provide various functions to the first semiconductor layer S1 such as forming a contact with the first electrode 40 or relaxation of distortion caused by a difference in lattice constant between the substrate 10 and the light absorbing layer 24 by using the buffer layers 21 and 22.

In addition, in the semiconductor light-receiving element 1 according to this embodiment, the buffer layer 22 has the first conductivity type, and the carrier concentration of the buffer layer 22 is higher than the carrier concentration of the capacitance reducing layer 23. Accordingly, a deterioration in response performance can be reliably suppressed.

In addition, in the semiconductor light-receiving element 1 according to this embodiment, the thickness of the light absorbing layer 24 is from 0.6 μm to 1.8 μm. Accordingly, a traveling distance of electrons is shortened, and thus an increase in speed is achieved. In addition, in the semiconductor light-receiving element 1 according to this embodiment, the carrier concentration of the capacitance reducing layer 23 is from 1.5×10¹⁴ cm⁻³ to 5×10¹⁵ cm⁻³. Accordingly, it is possible to suitably deplete the capacitance reducing layer 23 when a bias is applied while reducing the barrier caused by the capacitance reducing layer 23.

In addition, in the semiconductor light-receiving element 1 according to this embodiment, the sensitivity wavelength region of the capacitance reducing layer 23 is 1.31 μm or less. Accordingly, in the capacitance reducing layer 23, it is possible to suppress absorption of light in a wavelength band for communication such as a band of 1.3 μm, a band of 1.55 μm, and a band of 1.6 μm.

In the above-described embodiment, one aspect of the semiconductor light-receiving element according to the invention is described. Therefore, the semiconductor light-receiving element according to the invention is not limited to the above-described aspect and may be modified. Next, modification examples will be described.

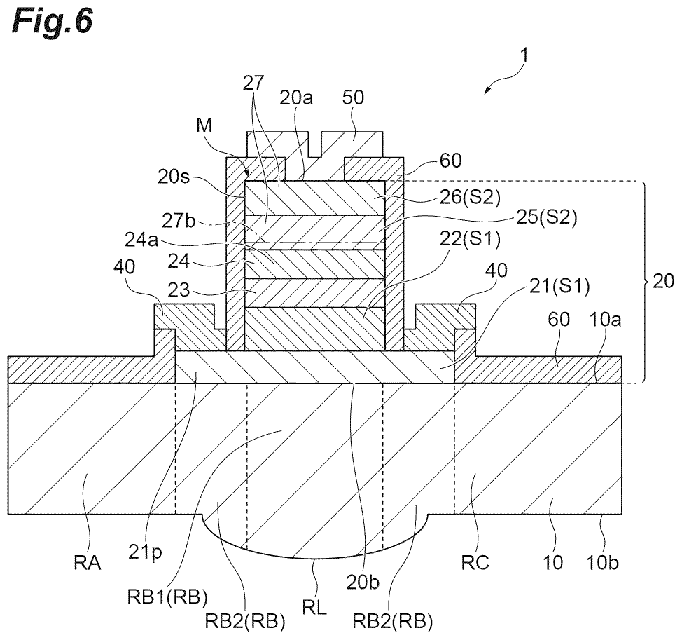

FIG. 6 is a cross-sectional view illustrating a semiconductor light-receiving element according to a modification example. The cross-section of FIG. 6 corresponds to a cross-section taken along line III-III in FIG. 2. In the example shown in FIG. 6, the entire second semiconductor layer S2 (that is, the cap layer 25 and the contact layer 26) is set as the second region 27 that has the second conductivity type (here, a P type, and as an example, a P⁺ type). That is, the second semiconductor layer S2 consists of the second region 27. The second semiconductor layer S2 can be formed, for example, by epitaxially growing a semiconductor layer that has the second conductivity type on the light absorbing layer 24.

In this case, the second region 27 that has the second conductivity type does not extend into the light absorbing layer 24. However, in this case, the second region 27 may include another light absorbing layer 27b that has the second conductivity type (here, a P type and as an example, a P⁺ type) laminated on the light absorbing layer 24. The light absorbing layer 27b is located on a side opposite to the capacitance reducing layer 23 with respect to the light absorbing layer 24. In this case, the entire light absorbing layer 24 becomes the first region 24a that has the first conductivity type. The light absorbing layer 27b may consist of the same material as the above-described material of the light absorbing layer 24, and may contain, for example, InGaAs, and consist of P⁺-InGaAs as an example.

The thickness of the light absorbing layer 27b may be larger or smaller than the thickness of the light absorbing layer 24. When the thickness of the light absorbing layer 27b is smaller than the thickness of the light absorbing layer 24, the response speed is improved. In the example shown in FIG. 6, contact with the second electrode 50 is made at the contact layer 26, but it is also possible to make contact with the second electrode 50 at the light absorbing layer 27b by providing the light absorbing layer 27b that has the second conductivity type.

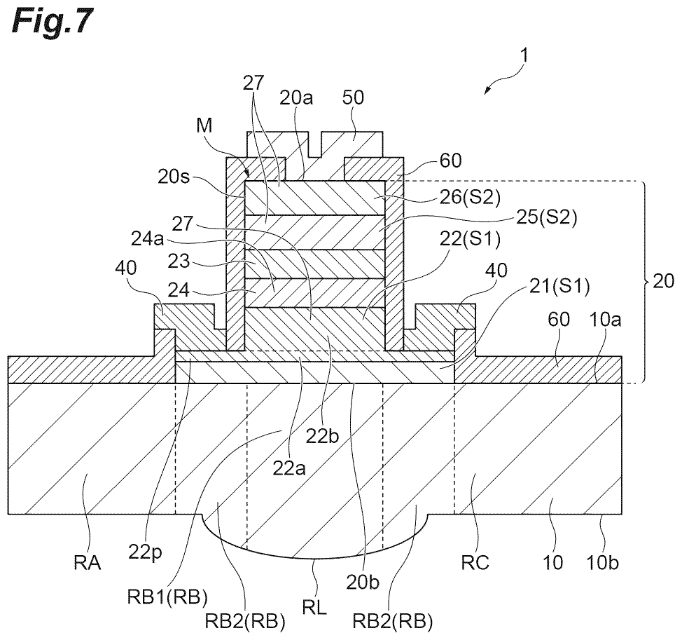

FIG. 7 is a cross-sectional view illustrating a semiconductor light-receiving element according to another modification example. The cross-section in FIG. 7 corresponds to a cross-section taken along line III-III in FIG. 2. In the example shown in FIG. 7, the buffer layer 21 and the buffer layer 22 have the second conductivity type (here, a P type, and for example, a P⁺ type). The buffer layer 21 contains, for example, InP, and consists of P⁺-InP as an example. The buffer layer 22 contains, for example, InP or InGaAsP, and consists of P⁺-InP or P⁺-InGaAsP as an example.

In addition, in the example shown in FIG. 7, the cap layer 25 and the contact layer 26 (second region 27) have the first conductivity type (here, an N type, and for example, an N⁺ type). The cap layer 25 contains, for example, InP or InGaAsP. As an example, the cap layer 25 consists of N⁺-InP or N⁺-InGaAsP. The contact layer 26 contains, for example, InGaAs, and consists of N⁺-InGaAs as an example. The conductivity types of the capacitance reducing layer 23 and the light absorbing layer 24 are similar to those in the above-described embodiment.

In this way, in the example shown in FIG. 7, the first semiconductor layer S1 has the second conductivity type, and the second semiconductor layer S2 has the first conductivity type. The capacitance reducing layer 23 is located between the light absorbing layer 24 and the second semiconductor layer S2. Accordingly, in this example, the first semiconductor layer S1 includes the second region 27 that has the second conductivity type and forms a PN junction with the light absorbing layer 24.

In this way, the capacitance reducing layer 23 is located between one semiconductor layer of the first semiconductor layer S1 and the second semiconductor layer S2 (the first semiconductor layer S1 in the above-described embodiment and the example of FIG. 6, and the second semiconductor layer S2 in the example of FIG. 7) and the light absorbing layer 24. The other semiconductor layer of the first semiconductor layer S1 and the second semiconductor layer S2 (the second semiconductor layer S2 in the above-described embodiment and the example of FIG. 6, and the first semiconductor layer S1 in the example of FIG. 7) includes the second region 27 that has the second conductivity type and forms a PN junction with the light absorbing layer 24 (first region 24a).

Note that, in the example of FIG. 7, the buffer layer 22 includes a first layer 22a provided across the region RB1 to the region RB2 of the substrate 10, and a second layer 22b that is formed on the region RB1 and does not reach the region RB2. The first layer 22a and the second layer 22b are laminated sequentially from the substrate 10 side. The first layer 22a includes a portion 22p exposed from the semiconductor mesa M (that is, the second layer 22b) and the protective film 60, and is connected to the first electrode 40 at the portion 22p.

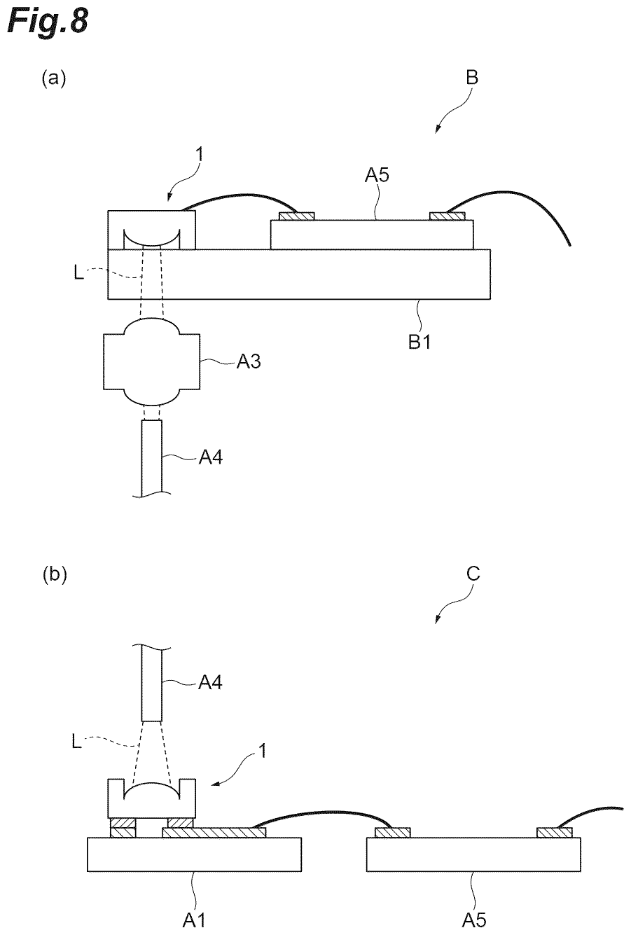

FIG. 8 is a view illustrating a modification example related to a mounting method of a semiconductor light-receiving element. In an optical device B shown in (a) in FIG. 8, the semiconductor light-receiving element 1 is mounted on a glass substrate B1 so that the rear surface 10b of the substrate 10 faces the glass substrate B1, and is electrically connected directly to the transimpedance amplifier A5 similarly mounted on the glass substrate B1 by a wire. The lens A3 and the optical fiber A4 are arranged on a surface side of the glass substrate B1 which is opposite to a surface on which the semiconductor light-receiving element 1 is mounted, and light L is incident to the semiconductor light-receiving element 1 from the rear surface 10b side through the glass substrate B1. In an optical device C shown in (b) in FIG. 8, the lens A3 is omitted as compared with the optical device A shown in FIG. 1. Furthermore, the semiconductor light-receiving element 1 may be directly mounted on the transimpedance amplifier A5.

In this way, various aspects are considered for the mounting method of the semiconductor light-receiving element 1 and the optical device including the semiconductor light-receiving element 1. In the above-described examples, the semiconductor light-receiving element 1 is used as a rear-surface incident type. However, the semiconductor light-receiving element 1 may be configured as a front surface-incident type in which light is incident from a side opposite to the substrate 10 toward the semiconductor lamination portion 20. That is, the semiconductor light-receiving element 1 may be configured to receive light incident from the front surface 10a side of the substrate 10. In this case, an opening may be formed so that a light-receiving unit is exposed to the second electrode 50 provided on the light-receiving portion (second region 27).

Furthermore, in a case where the semiconductor light-receiving element 1 is used as the rear-surface incident type (type in which light is incident from the substrate 10 side toward the semiconductor lamination portion 20), the light may be incident from a side surface of the substrate 10 toward the semiconductor lamination portion 20 by reflection or refraction at the side surface of the substrate 10. In this case, a light incident surface of the substrate 10 may be the front surface 10a or the rear surface 10b. Note that, the side surface of the substrate 10 is a surface that intersects the rear surface 10b and the front surface 10a between the rear surface 10b and the front surface 10a. According to this configuration, it is possible to form an optical path, which is oblique to the thickness direction of the light absorbing layer 24, in the light absorbing layer 24, and further suppression of a decrease in sensitivity, and an increase in the speed can be achieved.

Furthermore, the semiconductor light-receiving element 1 may be configured as a side incident type in which light is incident from the side surface 20s of the semiconductor lamination portion 20 toward the light absorbing layer 24. In this case, light may be incident to the side surface 20s via a waveguide formed on the substrate 10, or light that has propagated through a space or an optical fiber may be coupled to an end face of the light absorbing layer 24.

In addition, in the above-described example, the thickness of the light absorbing layer 24 is 0.7 μm, and the In composition x of the light absorbing layer 24 is 0.59 as an example. However, the thickness of the light absorbing layer 24 may be 1.8 μm or less, and the In composition x may be 0.55 or more. In particular, the In composition x of the light absorbing layer 24 may be 0.57 or more, and the thickness of the light absorbing layer may be 1.2 μm or less. Furthermore, the In composition x of the light absorbing layer 24 may be 0.59 or more, and the thickness of the light absorbing layer 24 may be 0.7 μm or less. In these cases, an increase in speed is achieved due to a further reduction in the thickness of the light absorbing layer.

Note that, examples of combinations of each wavelength band and the thickness of the light absorbing layer 24 and the In composition x of the light absorbing layer 24 are listed below. For example, the following (5) can be configured not only for the C-band but also for the O-band and the L-band.

### (1) C-Band

Sensitivity: 0.86 A/W or more.

Cutoff frequency: 20 GHz or more (for 28 GB or the like).

Thickness of absorption layer: 1.5 μm (details: N⁻ region (first region 24a): 1.3 μm, P⁺ region (fifth region 27a): 0.2 μm).

In composition x: x=0.55.

### (2) C-Band

Sensitivity: 0.90 A/W or more.

Cutoff frequency: 20 GHz or more (for high sensitivity product of 28 GB).

Thickness of absorption layer: 1.5 μm (details: N⁻ region (first region 24a): 1.3 μm, P⁺ region (fifth region 27a): 0.2 μm).

In composition x: x=0.57.

### (3) C-Band

Sensitivity: 0.80 A/W or more.

Cutoff frequency: 30 GHz or more (for 56 GB or the like).

Thickness of absorption layer: 1.2 μm (details: N⁻ region (first region 24a): 1.0 μm, P⁺ region (fifth region 27a): 0.2 μm).

In composition x: x=0.57.

### (4) C-Band

Sensitivity: 0.85 A/W or more.

Cutoff frequency: 30 GHz or more (for high sensitivity product of 56 GB).

Thickness of absorption layer: 1.2 μm (details: N⁻ region (first region 24a): 1.0 μm, P⁺ region (fifth region 27a): 0.2 μm).

In composition x: x=0.59.

### (5) C-Band

Sensitivity: 0.7 A/W or more.

Cutoff frequency: 45 GHz or more (for 96 GB or the like).

Thickness of absorption layer: 0.7 μm (details: N⁻ region (first region 24a): 0.5 μm, P⁺ region (fifth region 27a): 0.2 μm).

In composition x: x=0.59.

### (6) C-Band

Sensitivity: 0.90 A/W or more.

Cutoff frequency: 16 GHz or more (for 25 GB or the like).

Thickness of absorption layer: 1.8 μm (details: N⁻ region (first region 24a): 1.6 μm, P⁺ region (fifth region 27a): 0.2 μm).

In composition x: x=0.55.

### (7) C-Band

Sensitivity: 0.93 A/W or more.

Cutoff frequency: 16 GHz or more (for 25 GB or the like).

Thickness of absorption layer: 1.8 μm (details: N⁻ region (first region 24a): 1.6 μm, P⁺ region (fifth region 27a): 0.2 μm).

In composition x: x=0.57 .

In addition, in the semiconductor light-receiving element 1, the semiconductor lamination portion 20 may include a third semiconductor layer that is provided between the light absorbing layer 24 and the cap layer 25, and has a band gap between the band gap of the light absorbing layer 24 and the band gap of the cap layer 25. The third semiconductor layer has a first conductivity type (for example, N⁻ type) and consists of N⁻-InAsGaP as an example. In this case, the difficulty in extracting carriers due to a sudden change in the band gap between the cap layer 25 and the light absorbing layer 24 is suppressed.

In the semiconductor light-receiving element 1, the buffer layer 21 may be doped with Fe to be semi-insulated and increased in thickness.

In this case, crystallinity is improved. Alternatively, in the semiconductor light-receiving element 1, the buffer layer 21 may be non-doped.

In addition, in the semiconductor light-receiving element 1, a strain relaxation layer (buffer layer) in which the lattice constant changes continuously from the substrate 10 toward the light absorbing layer 24 to be close to the lattice constant of the light absorbing layer 24 may be used. In the above-described example, the semiconductor light-receiving element 1 includes the cap layer 25 and the contact layer 26 laminated sequentially on the light absorbing layer 24, and the second electrode 50 is connected to the surface of the second region 27 formed in the contact layer 26. However, in the semiconductor light-receiving element 1, the cap layer 25 may be omitted, and the contact layer 26 may be formed directly on the light absorbing layer 24. Even in this case, the contact resistance of the second electrode 50 is lowered.

Furthermore, in the semiconductor light-receiving element 1, the substrate 10 may be removed by, for example, etching or polishing, and then the semiconductor lamination portion 20 may be bonded to a substrate consisting of an insulating substance such as quartz or a semi-insulating semiconductor material other than InP (for example, gallium arsenide). In other words, in the semiconductor light-receiving element 1, the substrate 10 may contain an insulating substance or a semi-insulating semiconductor and be configured separately from the semiconductor lamination portion 20, and the semiconductor lamination portion 20 may be bonded (for example, directly) to the substrate 10. In this way, when manufacturing the semiconductor light-receiving element 1 by separately configuring and bonding the substrate 10 and the semiconductor lamination portion 20, it possible to increase the diameter and it is possible to reduce the cost by fabricating optical components with inexpensive materials.

Note that, when bonding the substrate 10 and the semiconductor lamination portion 20 which are configured separately from each other, direct bonding or bonding using a resin can be employed. When a resin is used in bonding between the substrate 10 and the semiconductor lamination portion 20, there is a possibility that light in the target wavelength band may be absorbed depending on properties of the resin, but this is not possible with direct bonding.

### INDUSTRIAL APPLICABILITY

A semiconductor light-receiving element capable of suppressing a deterioration in response performance.

### REFERENCE SIGNS LIST

1: semiconductor light-receiving element, 10: substrate, 20: semiconductor lamination portion, 21, 22: buffer layer, 23: capacitance reducing layer, 24: light absorbing layer, 24a: first region, 27b: light absorbing layer, 25: cap layer, 26: contact layer, 27: second region, 28: third region, S1: first semiconductor layer, S2: second semiconductor layer.

1. A semiconductor light-receiving element comprising:
a substrate;
a semiconductor lamination portion formed on the substrate; and
first and second electrodes electrically connected to the semiconductor lamination portion,
wherein the semiconductor lamination portion includes,
a light absorbing layer that contains InGaAs and includes a first region that has a first conductivity type,
a first semiconductor layer located between the substrate and the light absorbing layer,
a second semiconductor layer located on a side opposite to the substrate with respect to the light absorbing layer, and
a capacitance reducing layer that has the first conductivity type, consists of any one of InP, InGaAsP, InAsP, and AlInGaAs, and is located between one semiconductor layer from among the first semiconductor layer and the second semiconductor layer and the light absorbing layer,
the other semiconductor layer from among the first semiconductor layer and the second semiconductor layer includes a second region that has a second conductivity type and forms a PN junction with the first region of the light absorbing layer,
the first electrode is connected to the first semiconductor layer,
the second electrode is connected to the second semiconductor layer,
a carrier concentration of the capacitance reducing layer is 5×10¹⁵ cm⁻³ or less, and is higher than a carrier concentration of the first region of the light absorbing layer, and
a band gap of the capacitance reducing layer is larger than a band gap of the light absorbing layer.

2. The semiconductor light-receiving element according to claim 1,
wherein the other semiconductor layer includes a third region that has the first conductivity type and surrounds the second region when viewed from a lamination direction of the semiconductor lamination portion.

3. The semiconductor light-receiving element according to claim 2,
wherein the second region extends to the inside of the light absorbing layer from the other semiconductor layer.

4. The semiconductor light-receiving element according to claim 1,
wherein the other semiconductor layer consists of the second region.

5. The semiconductor light-receiving element according to claim 4,
wherein the second region includes another light absorbing layer that has the second conductivity type and is laminated on the light absorbing layer.

6. The semiconductor light-receiving element according to claim 1,
wherein the first semiconductor layer includes a buffer layer.

7. The semiconductor light-receiving element according to claim 6,
wherein the buffer layer has the first conductivity type, and a carrier concentration of the buffer layer is higher than the carrier concentration of the capacitance reducing layer.

8. The semiconductor light-receiving element according to claim 1,
wherein the thickness of the light absorbing layer is 0.6 μm or more and 1.8 μm or less.

9. The semiconductor light-receiving element according to claim 1,
wherein a carrier concentration in the first region of the light absorbing layer is 1×10¹⁴ cm⁻³ or more and 3×10¹⁵ cm⁻³ or less.

10. The semiconductor light-receiving element according to claim 1,
wherein the thickness of the capacitance reducing layer is 0.1 μm or more and 3.0 μm or less.

11. The semiconductor light-receiving element according to claim 1,
wherein the carrier concentration of the capacitance reducing layer is 1.5×10¹⁴ cm⁻³ or more and 5×10¹⁵ cm⁻³ or less.

12. The semiconductor light-receiving element according to claim 1,
wherein a sensitivity wavelength region of the capacitance reducing layer is 1.31 μm or less.

13. The semiconductor light-receiving element according to claim 6,
wherein the thickness of the buffer layer is 0.5 μm or more and 2.5 μm or less.

14. The semiconductor light-receiving element according to claim 6,
wherein a carrier concentration of the buffer layer is 5×10¹⁶ cm⁻³ or more and 5×10¹⁸ cm−³ or less.
